(19) United States
(12) Patent Application Publication
(10) Pub. No.: US 2015/0129288 A1
(43) Pub. Date: May 14, 2015

(54) CIRCUIT SUBSTRATE AND METHOD FOR MAKING THE SAME

(71) Applicant: TAIWAN GREEN POINT ENTERPRISES CO., LTD., TAICHUNG CITY (TW)

(72) Inventors: Pen-Yi LIAO, Taichung City (TW); Tsung-Han WU, Taichung City (TW); Fu-Pin TANG, Taichung City (TW); Mei-Chun CHEN, Taichung City (TW); Yu-Jen CHOU, Taichung City (TW)

(73) Assignee: TAIWAN GREEN POINT ENTERPRISES CO., LTD., TAICHUNG CITY (TW)

(21) Appl. No.: 14/079,191

(22) Filed: Nov. 13, 2013

(51) Int. Cl. H05K 1/02; H05K 1/03; C25D 5/02; H05K 1/09; H05K 3/46; H05K 3/00

(52) U.S. Cl. CPC H05K 1/0284; H05K 3/465; H05K 3/4661; H05K 3/0026; H05K 3/0041; C25D 5/02; H05K 1/0274; H05K 1/09; H05K 1/03
USPC 174/255; 427/97.2; 427/555; 427/534; 205/125

(57) ABSTRACT

A circuit substrate includes: a substrate; an insulating coating layered structure formed on the substrate, having top and bottom surfaces, and formed with a patterned recess that is indented inwardly from the top surface, that is disposed above the bottom surface, and that is defined by a recess-defining wall, the recess-defining wall having a bottom wall portion and a surrounding wall portion that extends upwardly from a periphery of the bottom wall portion; and a patterned metallic layered structure including an electroless plating metal layer formed on the bottom wall portion of the recess-defining wall.

### BACKGROUND OF THE INVENTION

1. Field of the Invention

The invention relates to a circuit substrate and a method for making the same, more particularly to a circuit substrate having a patterned metallic layered structure formed on an insulating coating layered structure.

2. Description of the Related Art

Conventionally, methods of forming a circuit substrate having a circuit pattern on a transparent insulating substrate can be performed by insert molding the circuit pattern into the insulating substrate or by laminating the circuit pattern with the insulating substrate. However, when the circuit pattern is modified or changed, adjustment of manufacturing equipments in the processing steps of the conventional method is time consuming.

U.S. Pat. No. 4,865,873 discloses a method for making a circuit substrate having a circuit pattern on a substrate. The method includes forming an insulating layer on a substrate, forming a water-soluble layer on the insulating layer, forming a patterned hole extending through the water-soluble layer and the insulating layer by laser ablation, forming an active metal layer in the patterned hole and on the water-soluble layer, and simultaneously electroless depositing a primary metal layer on the active metal layer and dissolving the water-soluble layer in an aqueous plating solution. Since the active metal layer covers a hole wall of the patterned hole as well as the water-soluble layer, electroless plating of the primary metal layer takes place not only at the hole wall but also at the surface of the water-soluble layer, which is undesirable. Although the water-soluble layer will be gradually dissolved in the aqueous plating solution during electroless plating, it may have adverse effect on electroless plating.

### SUMMARY OF THE INVENTION

Therefore, an object of the present invention is to provide a circuit substrate that can overcome the aforesaid drawbacks associated with the prior art.

According to one aspect of the present invention, there is provided a circuit substrate that comprises: a substrate; an insulating coating layered structure formed on the substrate, having top and bottom surfaces, and formed with a patterned recess that is indented inwardly from the top surface, that is disposed above the bottom surface, and that is defined by a recess-defining wall, the recess-defining wall having a bottom wall portion and a surrounding wall portion that extends upwardly from a periphery of the bottom wall portion; and a patterned metallic layered structure including an electroless plating metal layer formed on the bottom wall portion of the recess-defining wall.

According to another aspect of the present invention, there is provided a method for making a circuit substrate. The method comprises: providing a substrate; forming an insulating coating layered structure on the substrate, the insulating coating layered structure having a top surface; forming a patterned recess in the insulating coating layered structure such that the patterned recess is indented inwardly from the top surface, the patterned recess being defined by a recess-defining wall having a bottom wall portion and a surrounding wall portion extending upwardly from the bottom wall portion; and forming an electroless plating active layer on the recess-defining wall of the patterned recess and on the top surface of the insulating coating layered structure.

### BRIEF DESCRIPTION OF THE DRAWINGS

In drawings which illustrate an embodiment of the invention,

FIG. 1 is a perspective view of the preferred embodiment of a circuit substrate according to the present invention;

FIG. 2 is a perspective view illustrating a step of preparing a substrate in a method of making the preferred embodiment of the circuit substrate according to the present invention;

FIG. 3 is a perspective view illustrating a step of forming an insulating coating layered structure on the substrate in the method of making the preferred embodiment;

FIG. 4 is a perspective view illustrating a step of forming two patterned recesses in the insulating coating layered structure in the method of making the preferred embodiment;

FIG. 5 is a sectional view taken along line V-V of FIG. 4;

FIG. 6 is a perspective view illustrating a step of forming an electroless plating active layer in the method of making the preferred embodiment;

FIG. 7 is a sectional view taken along line VII-VII of FIG. 6;

FIG. 8 is a sectional view illustrating a step of removing two closed-loop portions of the electroless plating active layer in the method of making the preferred embodiment;

FIG. 9 is a sectional view illustrating a step of electroplating an electroplating metal layer on first regions of the electroless plating active layer in the method of making the preferred embodiment; and

FIG. 10 is a sectional view illustrating a step of removing a second region of the electroless plating active layer in the method of making the preferred embodiment.

### DETAILED DESCRIPTION OF THE PREFERRED EMBODIMENT

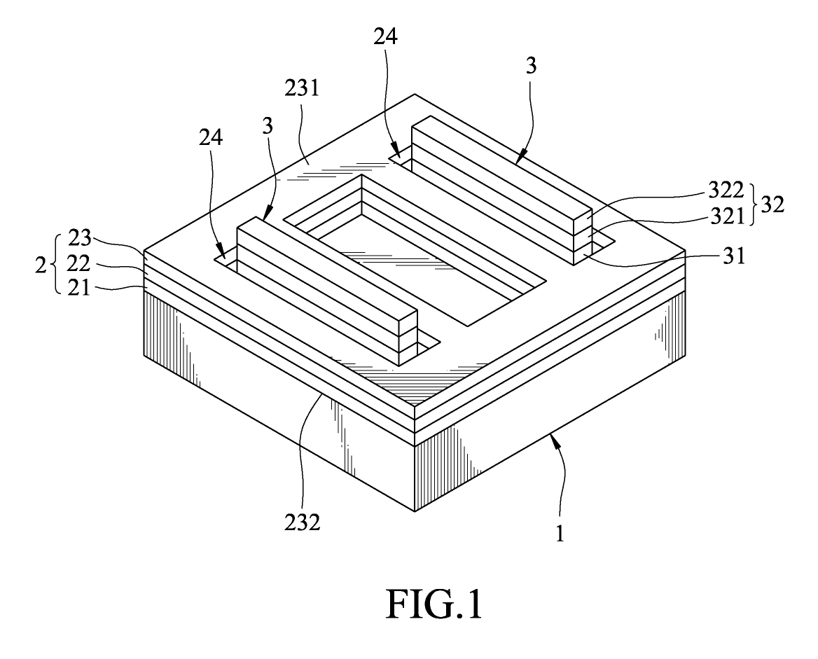

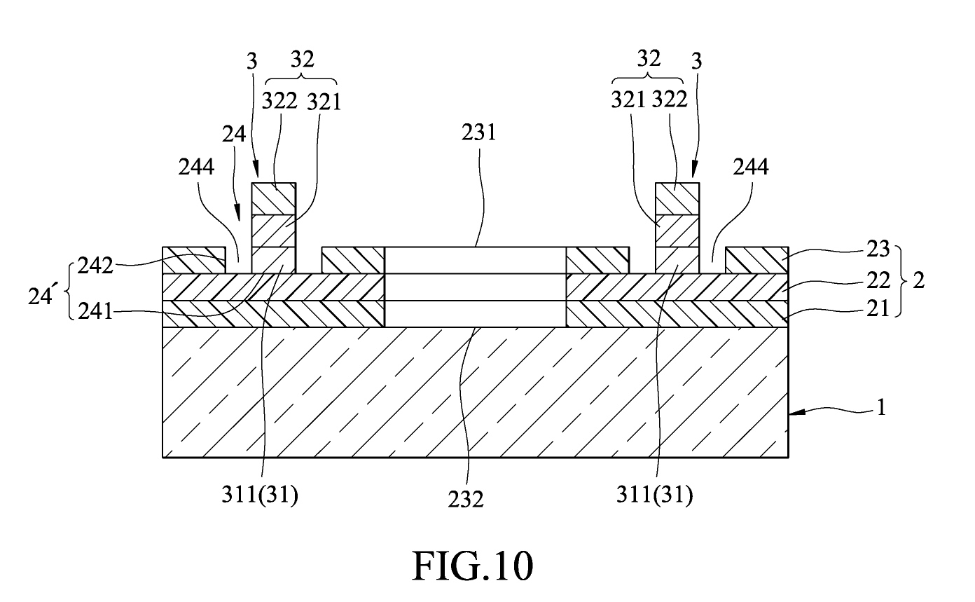

FIG. 1, in combination with FIG. 10, illustrates the preferred embodiment of a circuit substrate according to the present invention. The circuit substrate can be used for making products, such as circuit boards, touch panels, display panels, plastic shells and mobile phone shells.

The circuit substrate includes: a substrate 1; an insulating coating layered structure 2 formed on the substrate 1, having a top surface 231 and a bottom surface 232, and formed with two patterned recesses 24 that are indented inwardly from the top surface 231 and that are disposed above the bottom surface 232, each patterned recess 24 being defined by a recess-defining wall 24′, the recess-defining wall 24′ having a bottom wall portion 241 and a surrounding wall portion 242 that extends upwardly from a periphery of the bottom wall portion 241; and two patterned metallic layered structures 3, each of which includes an electroless plating metal layer 31 that is formed on the bottom wall portion 241 of the recess-defining wall 24′, and an electroplating metal layer 32 formed on the electroless plating metal layer 31. The electroless plating metal layer 31 of each patterned metallic layered structure 3 is formed on the bottom wall portion 241 of the recess-defining wall 24′ of a respective one of the patterned recesses 24, is disposed within the respective patterned recess 24, and is spaced apart from the surrounding wall portion 242 of the recess-defining wall 24′ by a spacing 244. Each patterned metallic layered structure 3 forms a circuit pattern that corresponds in shape to the pattern of the respective patterned recess 24.

Preferably, the substrate 1 is transparent. More preferably, the substrate 1 is made from a material selected from the group consisting of glass, polycarbonate, a combination of acryl resin and acrylonitrile butadiene styrene (ABS) resin, and a combination of polycarbonate and ABS resin.

Preferably, the insulating coating layered structure includes a lower coating layer 21 formed on the substrate 1 and defining the bottom surface 232 of the insulating coating layered structure 2, a middle coating layer 22 formed on the lower coating layer 21, and an upper coating layer 23 formed on the middle coating layer 22 and defining the top surface 231 of the insulating coating layered structure 2. Each patterned recess 24 extends from the top surface 231 through the upper coating layer 23, and has a bottom side that is confined by the middle coating layer 22. Each electroless plating metal layer 31 is formed on the middle coating layer 22. The upper coating layer 23 has a dark color (such as a black color), the middle coating layer 22 has a light color (such as a white color), and the lower coating layer 21 has a dark color (such as a black color).

Preferably, each of the lower, middle and upper coating layers 21, 22, 23 is made from a UV-curable ink material. When exposed to UV light, the UV-curable ink material can be rapidly cured or hardened within a short amount of time, which is beneficial to production rate of the circuit substrate.

Preferably, the electroless plating metal layer 31 of each patterned metallic layered structure 3 contains an active metal selected from the group consisting of palladium, rhodium, platinum, iridium, osmium, gold, nickel, iron, and combinations thereof. The electroless plating metal layer 31 further contains a first metal. The active metal and the first metal can be uniformly mixed in the electroless plating metal layer 31, or formed into an active layer and a chemical coating layer, respectively. The first metal is different from the active metal and is selected from the group consisting of copper, nickel, silver, and gold.

Preferably, the electroplating metal layer 32 of each patterned metallic layered structure 3 includes first and second metal sub-layers 321, 322. The first metal sub-layer 321 is formed on the electroless plating metal layer 31, and is made from a second metal selected from the group consisting of copper, nickel, and the combination thereof. The second metal sub-layer 322 is formed on the first metal sub-layer 321, and is made from a third metal selected from the group consisting of tin, silver, gold, palladium, and combinations thereof.

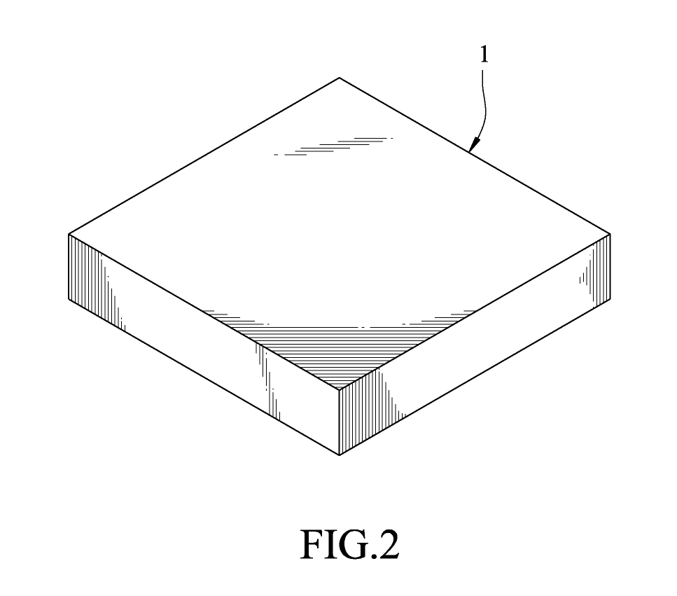

FIGS. 2 to 10 illustrate consecutive steps of a method for making the circuit substrate of the preferred embodiment according to the present invention.

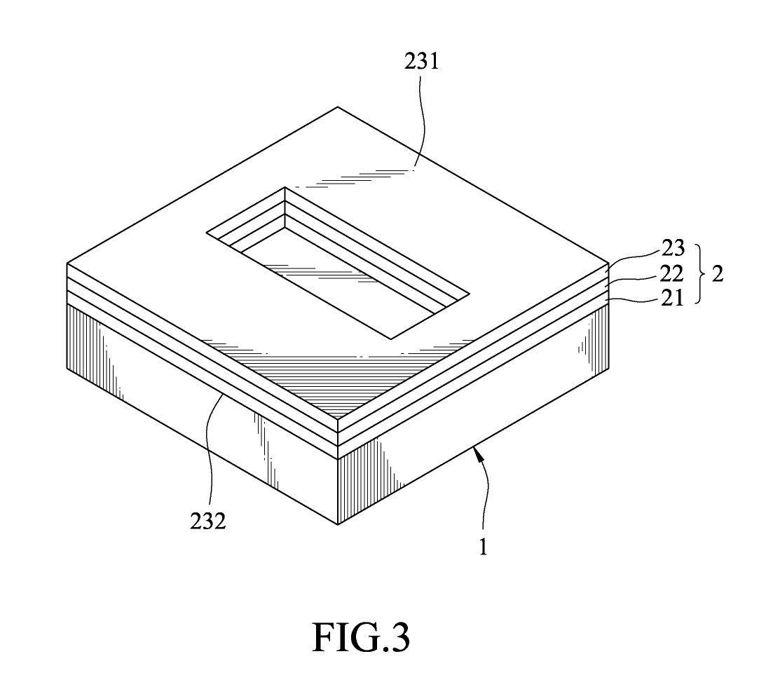

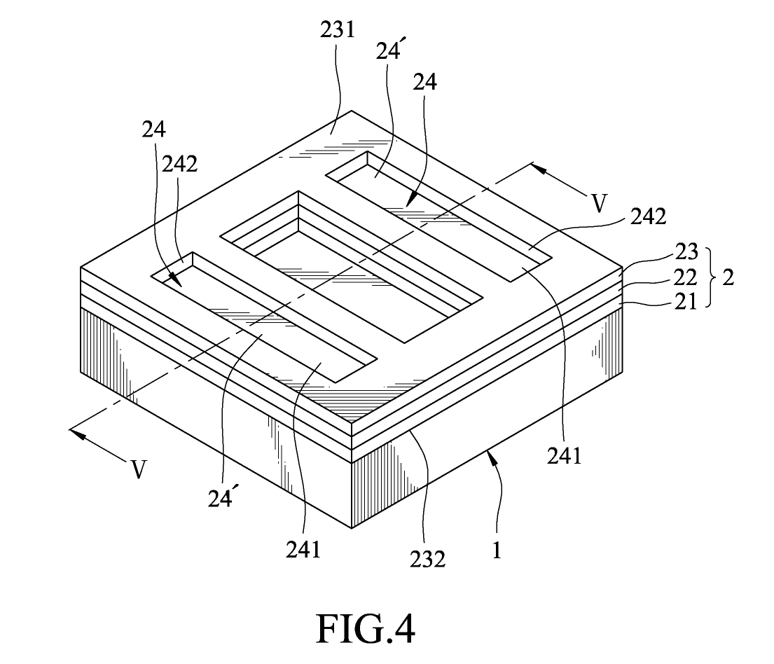

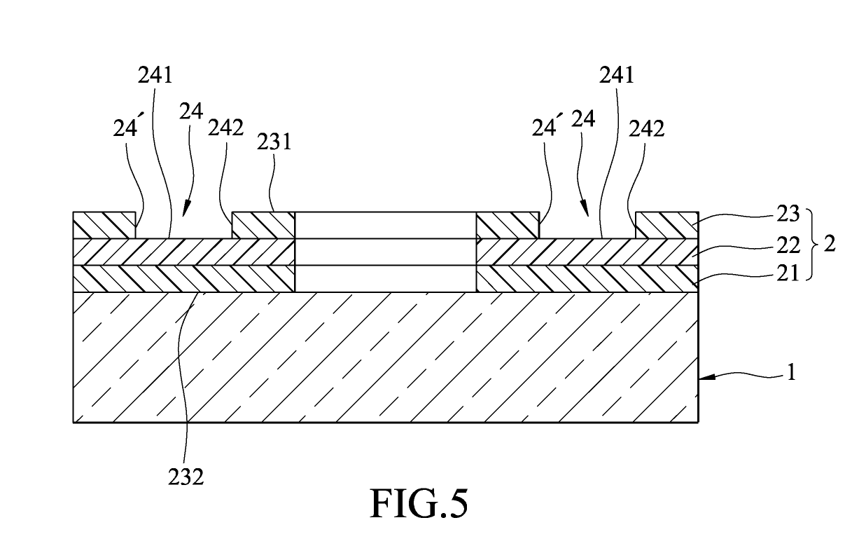

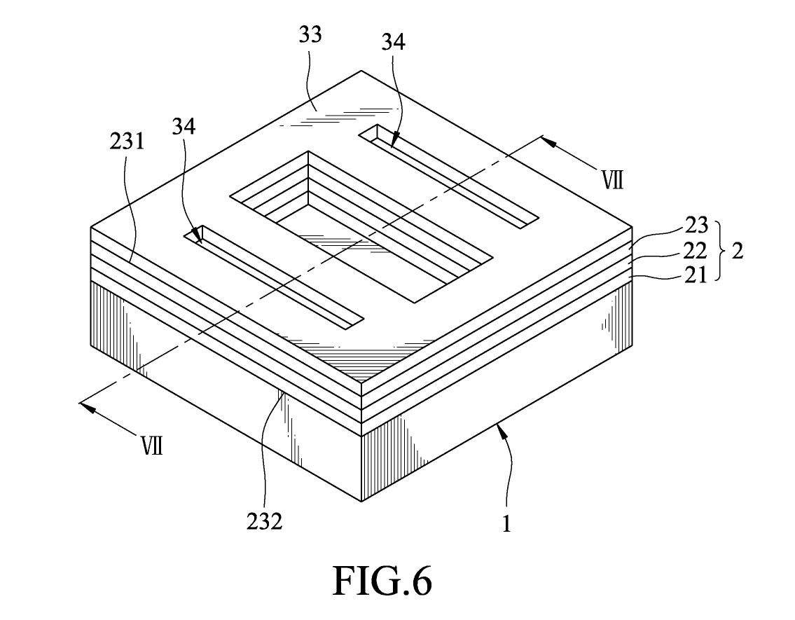

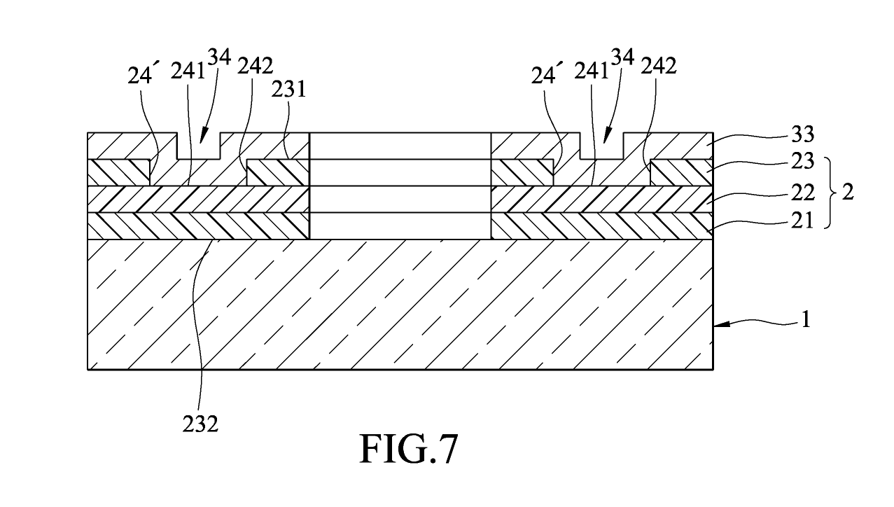

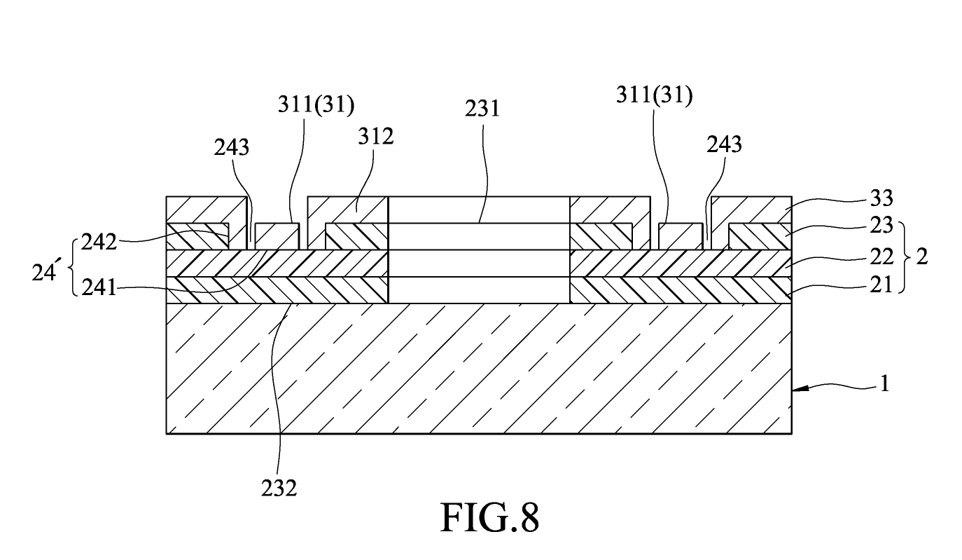

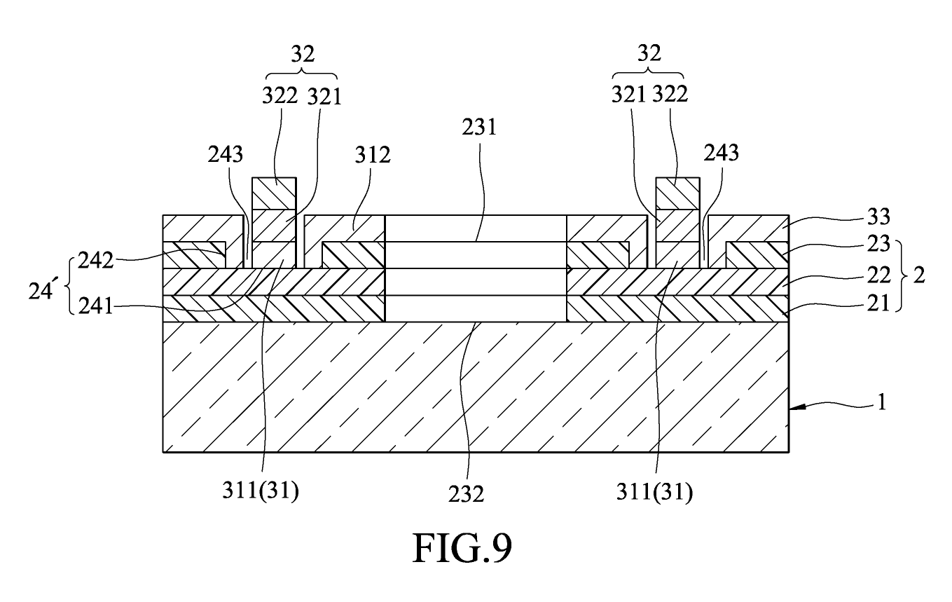

The method includes the steps of: providing a substrate 1 (see FIG. 2); forming an insulating coating layered structure 2 on the substrate 1 by sequentially printing a lower coating layer 21 on the substrate 1, a middle coating layer 22 on the lower coating layer 21, and an upper coating layer 23 on the middle coating layer 22, the insulating coating layered structure 2 having a loop shape, a top surface 231, a bottom surface 232 and a central hole that extends through the top and bottom surfaces 231, 232 and that exposes a central portion of the substrate 1 (see FIG. 3); forming two patterned recesses 24 in the insulating coating layered structure 2 such that each patterned recess 24 is indented inwardly from the top surface 231, each patterned recess 24 being defined by a recess-defining wall 24′ having a bottom wall portion 241 and a surrounding wall portion 242 extending upwardly from the bottom wall portion 241 (see FIGS. 4 and 5); forming an electroless plating active layer 33 on the recess-defining walls 24′ of the patterned recesses 24 and on the top surface 231 of the insulating coating layered structure 2 (see FIGS. 6 and 7), the electroless plating active layer 33 thus formed having two recesses 34 that are respectively disposed within the patterned recesses 24; removing two closed-loop portions of the electroless plating active layer 33 (see FIG. 8), each of which is disposed along a peripheral edge of the bottom wall portion 241 of a respective one of the recess-defining walls 24′ so as to form the electroless plating active layer 33 into two first regions 311 which are respectively disposed on the bottom wall portions 241 of the recess-defining walls 24′ and which respectively define the electroless plating metal layers 31 of the patterned metallic layered structures (see FIG. 10), and a second region 312 which is physically separated from each first region 311 by a gap 243; electroplating an electroplating metal layer 32 on each first region 311 of the electroless plating active layer 33 (see FIG. 9) by sequentially electroplating a first metal sub-layer 321 on each first region 311 and a second metal sub-layer 322 on the first metal sub-layer 321; and removing the second region 312 of the electroless plating active layer 33 from the top surface 231 of the insulating coating layered structure 2 and from the surrounding wall portions 242 of the recess-defining walls 24′ after the step of electroplating the electroplating metal layer 32, so that each electroless plating metal layer 31 is disposed within the patterned recess 24 and is spaced apart from the surrounding wall portion 242 of the recess-defining wall 24′ by a spacing 244 (see FIG. 10).

Each of the lower, middle, upper coating layers 21, 22, 23 is preferably formed by screen printing or other coating techniques.

Preferably, the patterned recesses 24 formed in the insulating coating layered structure 2 are formed by laser or plasma ablation. When the patterned recesses 24 are formed by laser or plasma ablation, the bottom wall portions 241 of the recess-defining walls 24′ can be roughened and be formed with micro-structures thereon, which can improve the bonding between the electroless plating metal layers 31 and the bottom wall portions 241. Moreover, since the upper coating layer 23 has a dark color and the middle coating layer 22 has a light color which can reflect most of the laser or plasma during formation of the patterned recesses 24, formation of the micro-structures on the middle coating layer 22 is facilitated and penetration of the laser or plasma through the middle coating layer 22 and further through the lower coating layer 21 to the substrate 1, which is likely to damage the substrate 1, can be prevented.

Formation of the electroless plating active layer 33 on the recess-defining walls 24′ of the patterned recesses 24 and on the top surface 231 of the insulating coating layered substrate 2 can be conducted by the following steps including forming catalytic seeds of the active metal on the recess-defining walls 24′ and on the top surface 231 using an activation solution that contains a salt of the active metal, followed by electroless plating the first metal on the recess-defining walls 24′ and on the top surface 231 in an electroless plating solution that contains a salt of the first metal. In one example, the active metal and the first metal are palladium and nickel, respectively, and the electroless plating can be operated under a temperature ranging from 70 to 80° C. for 1 to 2 minutes.

Preferably, the closed-loop portions of the electroless plating active layer 33 are removed by laser ablation. Preferably, the laser source used in the laser ablation is selected from IR or green line laser, and has a laser power ranging from 6 to 13 W and a repetition frequency ranging from 5 to 30 kHz.

With the inclusion of the patterned recesses 24 in the insulating coating layered structure 2 and the patterned metallic layered structures 3 in the circuit substrate of the present invention, the aforesaid drawbacks associated with the prior art can be alleviated.

What is claimed is:

1. A circuit substrate comprising:
a substrate;
an insulating coating layered structure formed on said substrate, having top and bottom surfaces, and formed with a patterned recess that is indented inwardly from said top surface, that is disposed above said bottom surface, and that is defined by a recess-defining wall, said recess-defining wall having a bottom wall portion and a surrounding wall portion that extends upwardly from a periphery of said bottom wall portion; and
a patterned metallic layered structure including an electroless plating metal layer formed on said bottom wall portion of said recess-defining wall.

2. The circuit substrate of claim 1, wherein said bottom wall portion is roughened by laser or plasma ablation so as to enhance the bonding between said electroless plating metal layer and said bottom wall portion.

3. The circuit substrate of claim 1, wherein said electroless plating metal layer is disposed within said patterned recess and is spaced apart from said surrounding wall portion of said recess-defining wall by a spacing.

4. The circuit substrate of claim 1, wherein said electroless plating metal layer contains an active metal selected from the group consisting of palladium, rhodium, platinum, iridium, osmium, gold, nickel, iron, and combinations thereof.

5. The circuit substrate of claim 4, wherein said electroless plating metal layer further contains a first metal different from said active metal and selected from the group consisting of copper, nickel, silver, and gold.

6. The circuit substrate of claim 1, wherein said patterned metallic layered structure further includes an electroplating metal layer formed on said electroless plating metal layer.

7. The circuit substrate of claim 6, wherein said electroplating metal layer includes first and second metal sub-layers, said first metal sub-layer being formed on said electroless plating metal layer, said second metal sub-layer being formed on said first metal sub-layer.

8. The circuit substrate of claim 1, wherein said insulating coating layered structure includes a middle coating layer and an upper coating layer formed on said middle coating layer and defining said top surface of said insulating coating layered structure, said patterned recess extending from said top surface through said upper coating layer and having a bottom side that is confined by said middle coating layer, said upper coating layer having a dark color, said middle coating layer having a light color, said electroless plating metal layer being formed on said middle coating layer.

9. The circuit substrate of claim 8, wherein said insulating coating layered structure further includes a lower coating layer formed on said substrate, said middle coating layer being formed on said lower coating layer.

10. The circuit substrate of claim 1, wherein said substrate is transparent.

11. A method for making a circuit substrate, comprising:
providing a substrate;
forming an insulating coating layered structure on the substrate, the insulating coating layered structure having a top surface;
forming a patterned recess in the insulating coating layered structure such that the patterned recess is indented inwardly from the top surface, the patterned recess being defined by a recess-defining wall having a bottom wall portion and a surrounding wall portion extending upwardly from the bottom wall portion; and
forming an electroless plating active layer on the recess-defining wall of the patterned recess and on the top surface of the insulating coating layered structure.

12. The method of claim 11, wherein said bottom wall portion is roughened by laser or plasma ablation so as to enhance the bonding between said electroless plating active layer and said bottom wall portion.

13. The method of claim 11, further comprising removing a portion of the electroless plating active layer that is disposed along a peripheral edge of the bottom wall portion of the recess-defining wall so as to form the electroless plating active layer into a first region which is disposed on the bottom wall portion, and a second region which is spaced apart from the first region.

14. The method of claim 13, further comprising electroplating an electroplating metal layer on the first region of the electroless plating active layer.

15. The method of claim 11, wherein the patterned recess is formed by laser or plasma ablation.

16. The method of claim 15, wherein the insulating coating layered structure includes a middle coating layer and an upper coating layer formed on the middle coating layer and defining the top surface of the insulating coating layered structure, the patterned recess extending from the top surface through the upper coating layer and having a bottom side that is confined by the middle coating layer, the upper coating layer having a dark color, the middle coating layer having a light color.

17. The method of claim 16, wherein the insulating coating layered structure further includes a lower coating layer formed on the substrate, the middle coating layer being formed on the lower coating layer.

18. The method of claim 14, further comprising removing the second region of the electroless plating active layer from the top surface of the insulating coating layered structure after the step of electroplating the electroplating metal layer on the first region of the electroless plating active layer.
